(19) United States
(12) Patent Application Publication
(10) Pub. No.: US 2020/0403580 A1
(43) Pub. Date: Dec. 24, 2020

(54) HIGH-FREQUENCY AMPLIFIER CIRCUITRY

(71) Applicants: Kabushiki Kaisha Toshiba, Tokyo (JP); Toshiba Electronic Devices & Storage Corporation, Tokyo (JP)

(72) Inventors: Toshiki Seshita, Kawasaki Kanagawa (JP); Yasuhiko Kuriyama, Yokohama Kanagawa (JP)

(21) Appl. No.: 16/871,191

(22) Filed: May 11, 2020

(30) Foreign Application Priority Data
Jun. 19, 2019 (JP) 2019-113596

(51) Int. Cl. H03F 1/52; H03F 3/193; H03F 3/21

(52) U.S. Cl. CPC H03F 1/523; H03F 2200/294; H03F 3/21; H03F 3/193

(57) ABSTRACT

A high-frequency amplifier circuitry includes a capacitor, a first transistor, a second transistor, and an ESD. The capacitor has one end connected to an input node. The first transistor has a gate connected to another end of the capacitor, and has a source grounded via an inductor. The second transistor is cascode-connected with the first transistor, has a gate grounded in a high-frequency manner, and outputs from a drain thereof a signal made by amplifying a signal output from a drain of the first transistor. The ESD protection circuitry includes a plurality of PN junction diodes, has a first terminal connected to the input node, has a second terminal grounded, and has a third terminal connected to the source of the first transistor.

### CROSS REFERENCE TO RELATED APPLICATIONS

This application is based upon and claims the benefit of priority from the prior Japanese Patent Application No. 2019-113596, filed on Jun. 19, 2019, the entire contents of which are incorporated herein by reference.

### FIELD

The embodiments of the present invention relate to high-frequency amplifier circuitry and a semiconductor device.

### BACKGROUND

For a Low Noise Amplifier (LNA), a SiGe bipolar process has been generally used, but the one by a CMOS process on a Silicon On Insulator (SOI) substrate is increased recently. This is because a highly-functional circuitry can be realized by incorporating a high-frequency FET (Field Effect Transistor) in the LNA. Generally, the thickness of the gate oxide film of the FET into which a signal is input is set to a minimum value allowable in the manufacturing process. In this case, the limits of the voltage between the gate and the source and the voltage between the gate and the drain are severe, so that application of a voltage having an amplitude exceeding the limits causes gate breakdown. Further, as a matter of course, Electro-Static Discharge (ESD) resistance is also required.

### BRIEF DESCRIPTION OF THE DRAWINGS

FIG. 1 is a circuitry diagram illustrating an example of an LNA according to an embodiment;

FIG. 2 is a diagram illustrating a mounting example of an LNA according to an embodiment;

FIG. 3 is a circuitry diagram illustrating an example of an LNA according to an embodiment;

FIG. 4 is a chart illustrating an S parameter in the case of FIG. 3;

FIG. 5 is a chart illustrating a voltage between terminals of a first transistor in the case of FIG. 3;

FIG. 6 is a circuitry diagram illustrating an example of an LNA according to an embodiment;

FIG. 7 is a chart illustrating an S parameter in the case of FIG. 6;

FIG. 8 is a chart illustrating a voltage between terminals of a first transistor in the case of FIG. 6;

FIG. 9 is a chart illustrating an S parameter according to a comparative example;

FIG. 10 is a chart illustrating a voltage between terminals of a first transistor according to a comparative example; and

FIG. 11 is a view illustrating a mounting example of a diode on an SOI according to an embodiment.

### DETAILED DESCRIPTION

According to one embodiment, a high-frequency amplifier circuitry includes a capacitor, a first transistor, a second transistor, and an ESD. The capacitor has one end connected to an input node. The first transistor has a gate connected to another end of the capacitor, and has a source grounded via an inductor. The second transistor is cascode-connected with the first transistor, has a gate grounded in a high-frequency manner, and outputs from a drain thereof a signal made by amplifying a signal output from a drain of the first transistor. The ESD protection circuitry includes a plurality of PN junction diodes, has a first terminal connected to the input node, has a second terminal grounded, and has a third terminal connected to the source of the first transistor.

Embodiments will now be explained with reference to the accompanying drawings. The present invention is not limited to the embodiments. Note that in the specification and attached drawings of this case, explanation and illustration of some components are omitted, changed or simplified for convenience of easy understanding and illustration, but it is construed that technical contents at the level capable of expecting the same functions are also contained in the embodiments. Further, in the drawings attached to the specification of this case, the scale, the dimensional ratio between length and breadth and so on are changed from the actual ones to be exaggerated for convenience of illustration and easy understanding.

First of all, the configuration of an LNA in common to embodiments is explained.

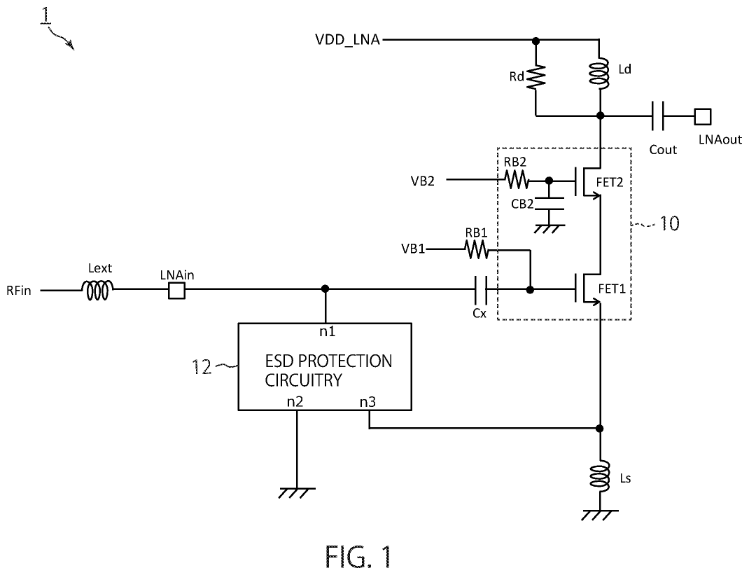

FIG. 1 illustrates a circuitry diagram of an LNA 1 according to an embodiment. The LNA 1 in FIG. 1 can be placed, for example, on an SOI substrate. A peripheral circuitry of the LNA 1, for example, an antenna switch and the LNA 1 may be placed on the same SOI substrate. The LNA 1 in FIG. 1 is used, for example, in a radio device such as a cellular phone, a smartphone or the like, but usage and mounting place do not matter.

The LNA 1 includes an input port LNAin and an output port LNAout. The LNA 1 amplifies a signal input from the input port LNAin through an external inductor Lext, and outputs the amplified signal from the output port. Hereinafter, an input RFin of the external inductor Lext is described also as a port 1 and the output port LNAout is described also as a port 2, and a value of an S parameter or the like between the ports is designated based on numbers of the ports.

The LNA 1 includes an amplifier circuitry 10 including a first transistor FET1 and a second transistor FET2, a capacitor Cx connected between the input port LNAin and the gate of the first transistor FET1, a source inductor Ls, an output matching resistor Rd, an output matching inductor Ld, and an output matching capacitor Cout. The LNA 1 further includes an ESD protection circuitry 12 having a first terminal n1 onnected to the input port LNAin, a second terminal n2 grounded, and a third terminal n3 onnected to the source of the first transistor FET1. The ESD protection circuitry 12 is a circuitry which prevents electrostatic discharge damage due to electro static discharge applied to the input port LNAin. The ESD protection circuitry 12 includes, for example, a plurality of PN junction diodes.

A high-frequency signal is input into the input port LNAin through the external inductor Lext. The input signal is biased by a bias voltage VB1 into the gate of the first transistor FET1 through the capacitor Cx and grounded through the source inductor Ls. The capacitor Cx and the source inductor function together with the external inductor Lext, as an input matching circuitry. Further, the capacitor Cx also has a function of removing a DC component of the signal. The input matching circuitry matches the input signal.

Between a power supply voltage VDD_LNA and the drain of the second transistor FET2, the output matching resistor Rd and the output matching inductor Ld are connected in parallel, and between the drain of the second transistor FET2 and the output port LNAout, the output matching capacitor Cout is onnected. From the output port LNAout, the input high-frequency signal is output after being amplified. More specifically, the signal is output after being amplified and matched by the source inductor Ls, the first transistor FET1, the second transistor FET2, and the output matching resistor Rd, the output matching inductor Ld, and the output matching capacitor Cout which are intended for output matching. Further, the amplifier circuitry 10 is configured so that, for example, the gate of the second transistor FET2 is grounded in a high-frequency manner and the high-frequency signal is appropriately amplified. This configuration is the operation equivalent to that of an LNA composed of a cascode-onnected amplifier circuitry in which a general grounded-source FET and a grounded-gate FET are onnected, and therefore its detailed explanation is omitted.

Note that various kinds of output matching circuitry elements are illustrated as examples, and are not essential points in the embodiments explained below. In other words, the output matching circuitry elements may have other configurations and may be provided outside the amplifier circuitry, in a broad sense, outside the LNA 1.

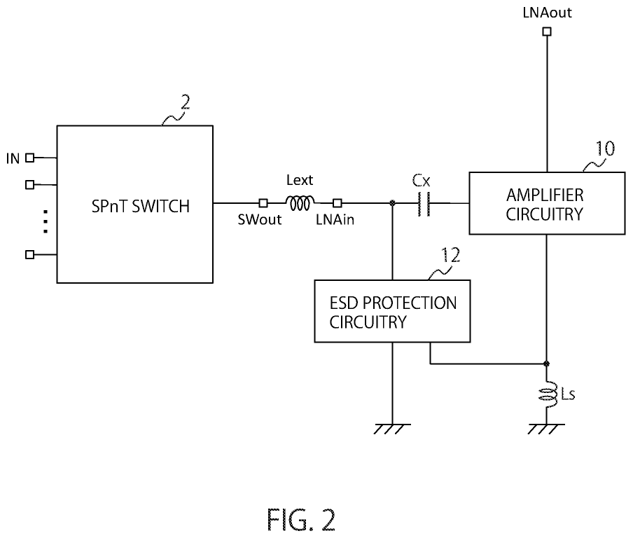

FIG. 2 is a mounting example of the LNA 1. The LNA 1 includes an amplifier circuitry 10, an ESD protection circuitry 12, a capacitor Cx, a source inductor Ls, and an SPnT switch 2 (Single Pole/n-Throw switch). The SPnT switch 2 is a band select switch which selects a signal to be amplified from among n input signals IN corresponding to n bands. For example, when either a Band7 (2620 MHz to 2690 MHz) or a Band41 (2496 MHz to 2690 MHz) is selected and amplified, an SPDT (Single-Pole Double-Throw) switch is provided at a stage preceding to the amplifier circuitry designed for the Band41 because the Band7 is included in the Band41.

In the LNA 1 explained below, the signal of the frequency belonging to the frequency band of the Band41 is selected and output as an example. The LNA 1 may include amplifier circuitries corresponding to many frequency bands in addition to the amplifier circuitry 10, and may output the signal from the SPnT switch 2 to an amplifier circuitry outside the LNA 1. In this case, a plurality of LNAs and so on may be provided on the same SOI substrate as that of the SPnT switch 2.

The signal output from the SPnT switch 2 is output once from a terminal SWout to the external part, and is input via the external inductor Lext as an input signal from the input port LNAin. An input matching circuitry may be provided in parallel with the external inductor Lext in the LNA 1.

The input signal is amplified in the amplifier circuitry 10 as explained above, and then output. The signal is protected by the ESD protection circuitry 12 from the electro static discharge from the input port LNAin side. The input signal is then amplified and output from the amplifier circuitry 10. An output matching circuitry may be provided as needed.

Note that though not illustrated in FIG. 2, each block is onnected to the power supply voltage Vdd, Vss (or GND) as necessary and thereby supplied with required power. Further, to each of the transistors in the circuitry, the bias voltage is applied to its gate from the external part as required. The LNA 1 may be provided with input terminals which accept input of the power supply voltage, the bias voltage and the like. Further, in the case of applying the bias voltage to the gate, a resistor, a grounded capacitor and so on which suppress the high-frequency noise may be provided according to the need.

Hereinafter, these circuitries are explained while illustrating more concrete embodiments. In the following embodiments, the frequency band of the Band41 is explained as above, but is not limited to this. For example, for other frequency bands, the performance is improved by the similar circuitry configuration through the use of circuitry elements in which the circuitry constants are changed.

### First Embodiment

Returning to FIG. 1, a first embodiment is explained. The output matching resistor Rd and the output matching capacitor Cout may be a variable resistor and a variable capacitor, respectively, to perform gain adjustment. Further, a bias control circuitry may be separately provided which controls a voltage to be applied to the gates of the transistors.

The LNA 1 includes the ESD protection circuitry 12 between the gate, the source of the first transistor FET1 and the ground point as illustrated in the drawing. In the ESD protection circuitry 12, one or more PN junction diodes are onnecte in series, for example, between the first terminal n1 and the second terminal n2 and between the first terminal n1 and the third terminal n3. As for these PN junction diodes, the sum of the junction areas of diodes which are onnected in a backward direction between the first terminal n1 and the second terminal n2 and the junction areas of diodes which are onnected in a backward direction between the first terminal n1 and the third terminal n3 is equal to the junction areas of diodes which are onnected in a forward direction between the first terminal n1 and the third terminal n3. The junction area here means the area of a region where a P region and an N region constituting the PN junction diode join in a semiconductor.

The junction area of the diode may be, for example, the sum of the junction areas of all of the diodes in the case where a plurality of diodes are provided between terminals. As another example, when counting a first stage, a second stage, . . . , from the side closer to the first terminal n1 as explained below, the junction areas of diodes existing at the same stage may be taken into consideration. For example, at the first stage, the sum of the junction areas of diodes which are onnected in the backward direction from the first terminal n1 to the second terminal n2 and diodes which are onnected in the backward direction from the first terminal n1 to the third terminal n3 is equal to the junction areas of diodes which are onnected in the forward direction from the first terminal n1 to the third terminal n3. This also applies to the other stages.

In the case where a plurality of stages exist, a diode which exists overlapped in a plurality of paths only needs to be considered in a range of real numbers. For example, in the case where the same diodes exist in a path in the backward direction from the first terminal n1 to the second terminal n2 and in a path in the backward direction from the first terminal n1 to the third terminal n3 and the sum regarding the junction areas of the diodes is found, it is only necessary to find the sum not as two diodes but as one diode.

As explained above, according to this embodiment, the provision of the ESD protection circuitry 12 having the PN junction diodes onnected to the input node, a ground node, and a node between the source inductor and the source of the first transistor based on the condition, makes it possible to offer the LNA 1 high in ESD resistance. Further, the formation of the LNA 1 on the SOI substrate makes it possible to easily and accurately form the PN junction diodes provided in the ESD protection circuitry 12.

As explained above, a gate oxide film thickness Tox of the first transistor FET1 is generally set to a minimum value in a manufacturing process. For example, assuming that Tox=2.5 nm, the maximum values of absolute values of a gate-source voltage Vgs and a gate-drain voltage Vgd shall not exceed 4 V. If a voltage amplitude more than that is applied, gate breakdown is caused. Hence, the gate-drain voltage Vgd of the first transistor FET1 is further designed to be equal to a breakdown withstand voltage Vgs_max at the timing when the gate-source voltage of the first transistor FET1 becomes an input power reaching the breakdown withstand voltage (Vgs_max), thereby making it possible to offer the LNA 1 improved also in excessive input resistance.

### Second Embodiment

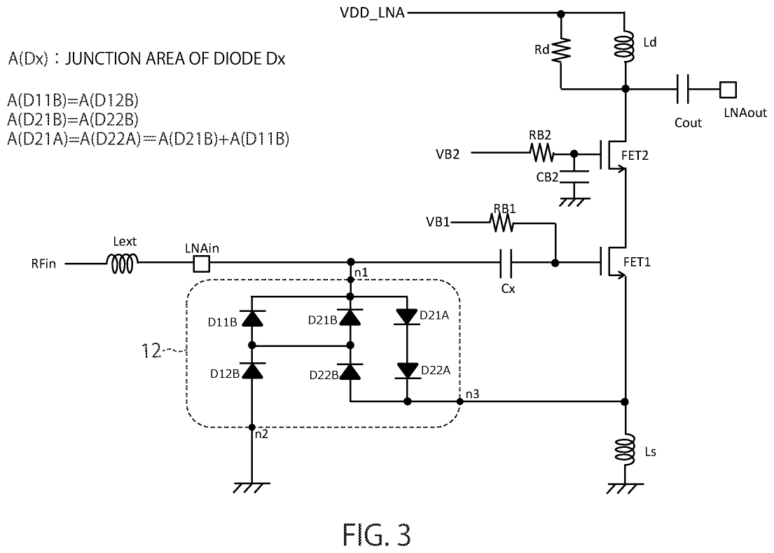

FIG. 3 is a circuitry diagram of an LNA 1 illustrating a more concrete mounting example of the ESD protection circuitry 12 of the first embodiment. The ESD protection circuitry 12 includes a first diode D11B, a second D12B, a third diode D21B, a fourth diode D22B, a fifth diode D21A, and a six diode D22A. Each of the first diode D11B to the six diode D22A is composed of a PN junction diode.

The first diode D11B has the cathode onnected to the first terminal n1, and has the anode onnected to the cathode of the second D12B, to the anode of the third diode D21B, and to the cathode of the fourth diode D22B. The second D12B has the cathode onnected to the anode of the first diode D11B, to the anode of the third diode D21B, and to the cathode of the fourth diode D22B, and has the anode onnected to the second terminal n2.

The third diode D21B has the cathode onnected to the first terminal n1, and has the anode onnected to the anode of the first diode D11B, to the cathode of the second D12B, and to the cathode of the fourth diode D22B. The fourth diode D22B has the cathode onnected to the anode of the first diode D11B, to the cathode of the second D12B, and to the anode of the third diode D21B, and has the anode onnected to the third terminal n3.

The fifth diode D21A has the anode onnected to the first terminal n1, and has the cathode onnected to the anode of the six diode D22A. The six diode D22A has the anode onnected to the cathode of the fifth diode D21A, and has the cathode onnected to the third terminal n3.

Of these diodes, the first diode D11B and the second diode D12B constitute diodes coupling the first terminal n1 and the second terminal n2 in the backward direction, the third diode D21B and the fourth diode D22B constitute diodes coupling the first terminal n1 and the third terminal n3 in the backward direction, and the fifth diode D21A and the six diode D22A constitute diodes coupling the first terminal n1 and the third terminal n3 in the forward direction.

In this embodiment, as explained above, these two paths are connected to each other between the first diode D11B and the second D12B coupling the first terminal n1 and the second terminal n2 and between the third diode D21B and the fourth diode D22B coupling the first terminal n1 and the third terminal n3.

The junction areas in these diodes are set to match the explanation of the above embodiment. For example, assuming that A(Dx) is the junction area of a diode Dx, the junction areas of the diodes connected in series are made equal as generally made. Namely, setting is made such that
the junction area of the first diode D11B (A(D11B))=the junction area of the second diode D12B (A(D12B))
the junction area of the third diode D21B (A(D21B))=the junction area of the fourth diode D22B (A(D22B))
the junction area of the fifth diode D21A (A(D21A))=the junction area of the sixth diode D22A (A(D22A)).
   Further, the sum (A(D11B)+A(D21B)) of the junction area of the first diode D11B (A(D11B)) and the junction area of the third diode D21B (A(D21B)) is made equal to the junction area of the fifth diode D21A (A(D21A)).

In the ESD protection circuitry 12 in which the PN junction diodes are connected in the above manner, for example, when positive static electricity discharge has occurred on the input side, the occurred static electricity discharge is evacuated from the first terminal n1 to the third terminal n3 by the forward direction characteristics of the diodes. From the third terminal n3 to the ground surface, the static electricity discharge is evacuated via the source inductor Ls. Further, when negative static electricity discharge has occurred, the static electricity discharge is evacuated through the path for discharging from the first terminal n1 to the second terminal n2 and the path for discharging from the first terminal n1 to the third terminal n3.

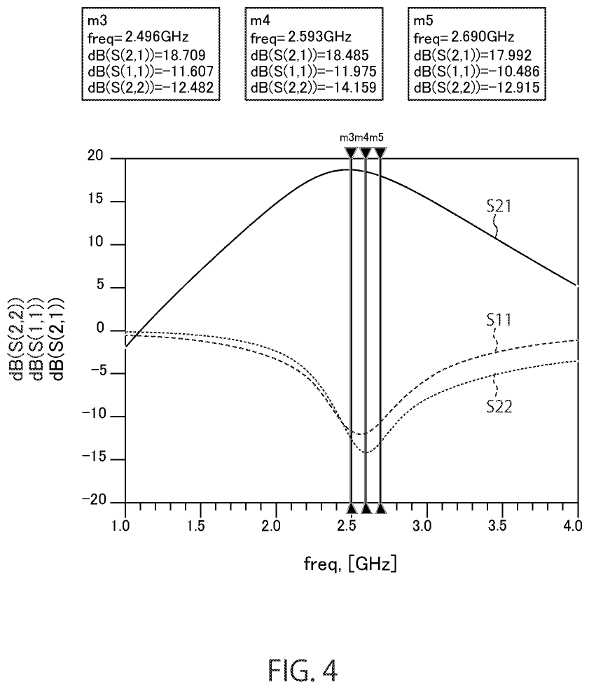

FIG. 4 is a chart illustrating an S parameter (Scattering Parameter) according to this embodiment. The horizontal axis indicates the frequency [GHz] and the vertical axis indicates the absolute value [dB] of the S parameter. Regarding the graph of the S parameter in the following drawings, m3 represents the observation at a frequency of 2496 MHz, m4 represents the observation at a frequency of 2593 MHz, and m5 represents the observation at a frequency of 2690 MHz. A solid line indicates S21 representing the transfer characteristic, a broken line indicates S11 representing the reflection characteristic at the input port, and a dotted line indicates S22 representing the reflection characteristic at the output port. As illustrated in FIG. 4, a gain (S21) at a level of 18 dB is obtained in the Band41. S11 indicates an excellent value such as −10.4 dB or less within the band, and S22 indicates an excellent value such as −12.4 dB or less within the band.

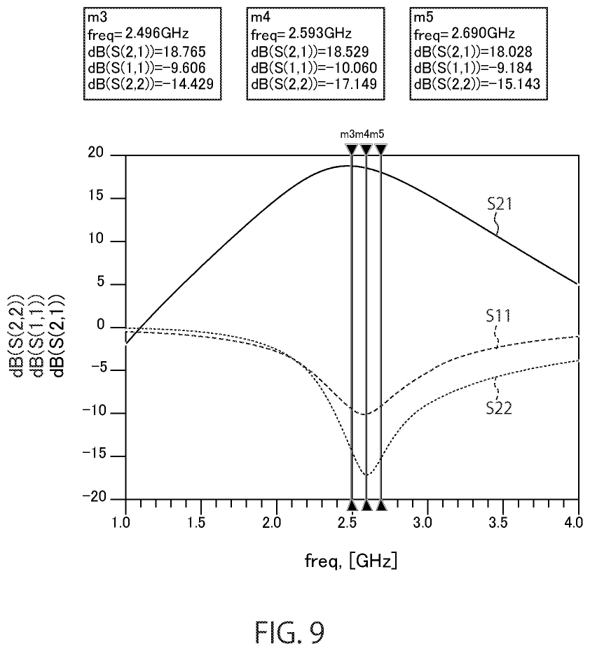

FIG. 9 is a chart illustrating an S parameter an LNA 1 according to a comparative example. The horizontal axis indicates the frequency [GHz] and the vertical axis indicates the absolute value [dB] of the S parameter. The LNA 1 used as the comparative example includes an ESD protection circuitry which does not have the third terminal n3 but has the first terminal n1 and the second terminal n2. In this ESD protection circuitry, diodes equivalent to the fifth diode D21A and the six diode D22A are connected in series in the forward direction from the first terminal n1 to the second terminal n2. Further, in parallel with the diodes connected in series, diodes having the same junction areas as the sum of the junction areas of the first diode D11B and the third diode D21B are connected in series at two stages in the backward direction from the first terminal n1 to the second terminal n2. The S parameter according to the comparative example is substantially the same in gain as in this embodiment, but is inferior to the S parameter according to this embodiment because S11 exceeds −10 dB.

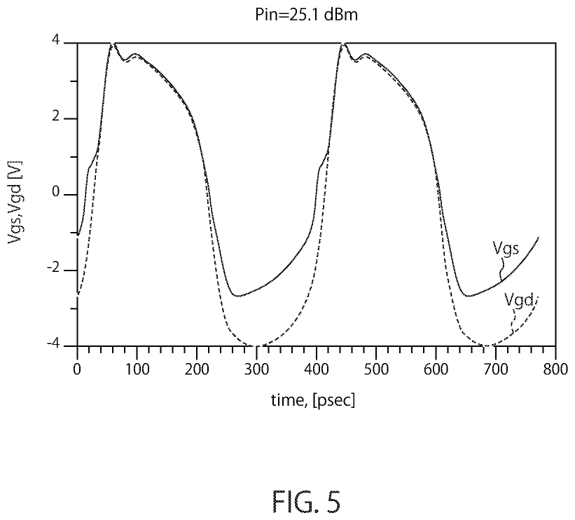

FIG. 5 is a chart illustrating waveforms of the gate-source voltage Vgs and the gate-drain voltage Vgd of the first transistor FET1 when the input power Pin is set to 25.1 dBm in this embodiment. The horizontal axis indicates the time [psec] and the vertical axis indicates the voltage [V]. A solid line indicates the gate-source voltage Vgs, and a broken line indicates the gate-drain voltage Vgd. It is found that when Pin is set to 25.1 dBm, the maximum values of the values of |Vgs| and |Vgd| are 4 V. Conversely, assuming that the acceptable amounts of |Vgs| and |Vgd| are 4 V, the maximum allowable input power is 25.1 dBm. The peak voltage between the gate and the source and the peak voltage between the gate and the drain depend on the ratio between the areas of the diodes included in the ESD protection circuitry 12. Hence, the area ratio of the diodes is defined so that (the absolute values of) the peak voltages become equal. The result defined in the above manner leads to the above relationship between the areas of the diodes.

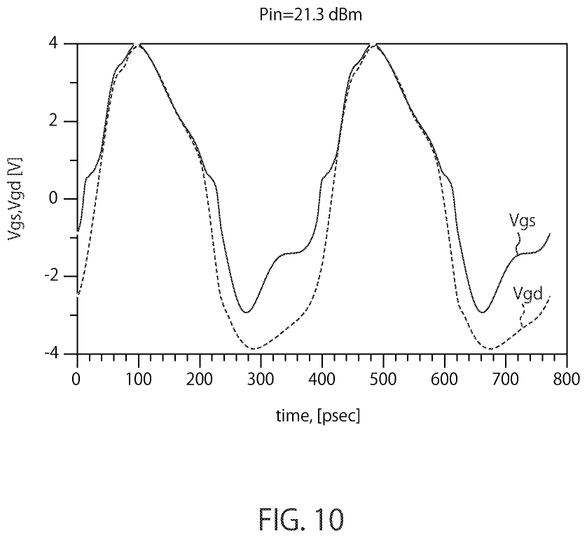

FIG. 10 is a chart illustrating waveforms of Vgs and Vgd of the first transistor FET1 when Pin=21.3 dBm in the LNA 1 according to the comparative example. It is found that when the maximum values of the values of |Vgs| and |Vgd| are 4 V, Pin is 21.3 dBm. The horizontal axis indicates the time [psec] and the vertical axis indicates the voltage [V]. A solid line indicates the gate-source voltage Vgs, and a broken line indicates the gate-drain voltage Vgd. The comparison between the charts shows that the LNA 1 including the ESD protection circuitry 12 according to this embodiment is higher by 3.8 dB in maximum allowable input power than the comparative example.

As explained above, according to this embodiment, the LNA 1 high in electro-static discharge resistance can be offered. The electro-static discharge resistance can be implemented by the provision of the ESD protection circuitry 12 including the PN junction diodes satisfying the above conditions. Further, the S parameter characteristic and the excessive input resistance can also be improved.

### Third Embodiment

In each of the above embodiments, the provision of the ESD protection circuitry 12 enables improvement of the ESD resistance and the excessive input resistance. In this embodiment, a clamp circuitry is further provided between the drain of the first transistor FET1 and the ground potential.

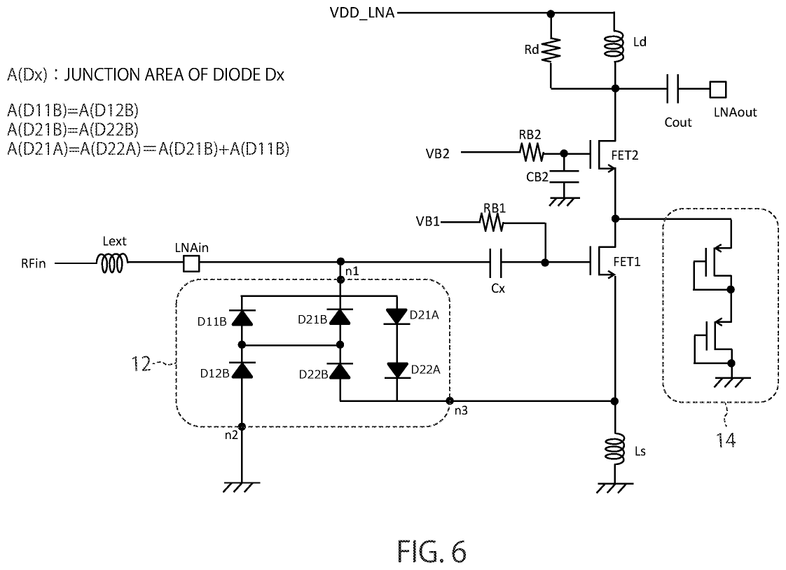

FIG. 6 is a circuitry diagram of an LNA 1 according to this embodiment. As illustrated in FIG. 6, the LNA 1 includes a clamp circuitry 14 between the drain of the first transistor FET1 and the ground potential. The other configuration is the same configuration of the above second embodiment. As in the second embodiment, the ESD protection circuitry 12 has high electro-static discharge resistance by the PN junction diodes. The clamp circuitry 14 in this drawing is the one made by coupling two p-type MOSFETs in series at two stages, but is not limited to this configuration. In other words, any clamp circuitry may be used as long as it adjusts the clamp voltage to an appropriate value and does not deteriorate the high-frequency characteristic.

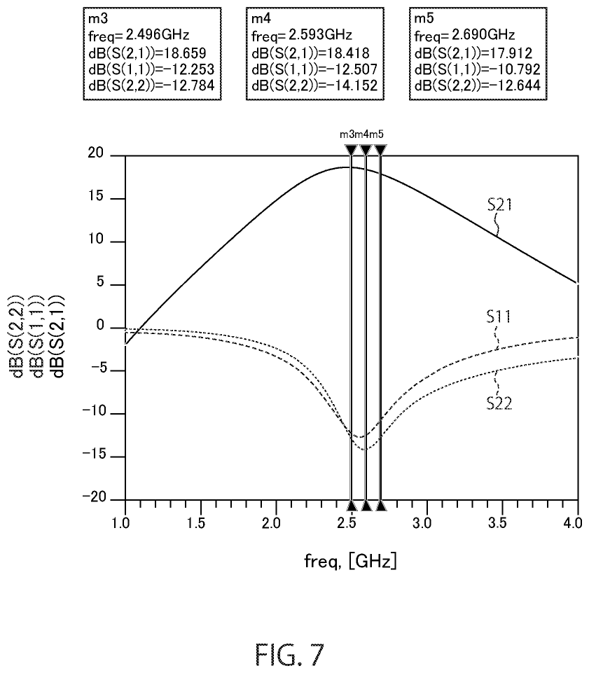

FIG. 7 is a chart illustrating an S parameter (Scattering Parameter) according to this embodiment. The horizontal axis indicates the frequency [GHz] and the vertical axis indicates the absolute value [dB] of the S parameter. A solid line indicates S21 representing the transfer characteristic, a broken line indicates S11 representing the reflection characteristic at the input port, and a dotted line indicates S22 representing the reflection characteristic at the output port. As illustrated in FIG. 7, a gain (S21) at a level of 18 dB is obtained in the Band41. S11 indicates an excellent value such as −10.7 dB or less within the band, and S22 indicates an excellent value such as −12.6 dB or less within the band.

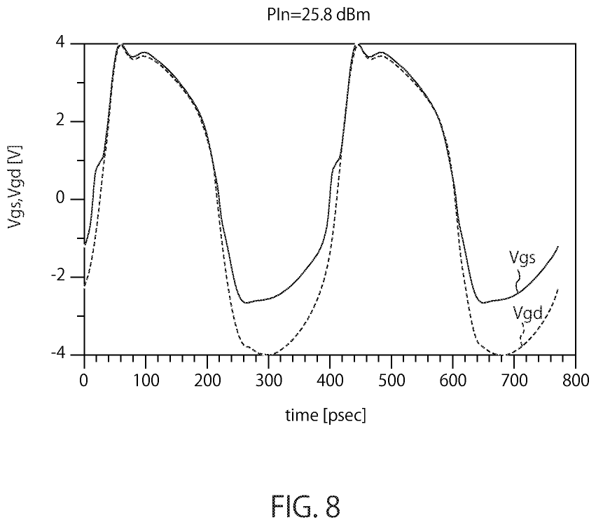

FIG. 8 is a chart illustrating waveforms of the gate-source voltage Vgs and the gate-drain voltage Vgd of the first transistor FET1 when the input power Pin is set to 25.8 dBm in this embodiment. The horizontal axis indicates the time [psec] and the vertical axis indicates the voltage [V]. A solid line indicates the gate-source voltage Vgs, and a broken line indicates the gate-drain voltage Vgd. It is found that when Pin is set to 25.8 dBm, the maximum values of the values of |Vgs| and |Vgd| are 4 V. Conversely, assuming that the acceptable amounts of |Vgs| and |Vgd| are 4 V, the maximum allowable input power is 25.8 dBm. This shows that the maximum allowable input power is higher by 4.5 dB than the comparative example illustrated in FIG. 10.

As explained above, also according to this embodiment, the LNA 1 high in electro-static discharge resistance can be offered. The electro-static discharge resistance can be implemented by the provision of the ESD protection circuitry 12 including the PN junction diodes satisfying the above conditions. Further, the provision of the clamp circuitry 14 enables further improvement in the S parameter characteristic and the excessive input resistance as well as the ESD resistance.

(Mounting Example of a PN Junction Diode on an SOI)

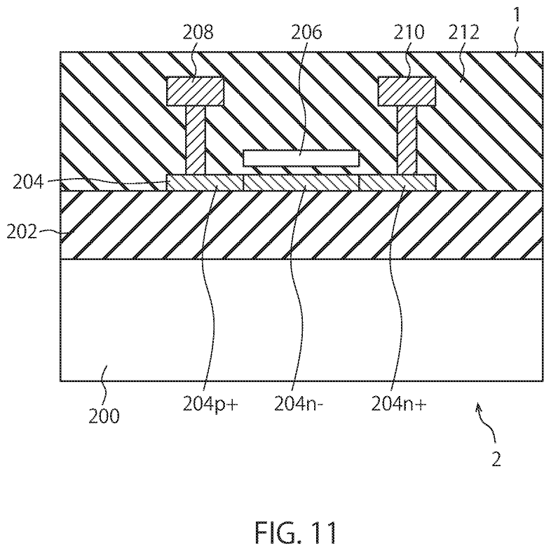

The LNA explained in each of the above embodiments may be formed on the SOI. FIG. 11 is a cross-sectional view illustrating an example of the formation of the PN junction diode on the SOT. The LNA 1 is formed on an SOI 2. The SOI 2 includes, for example, a substrate 200, a buried oxide film layer 202, an active layer 204, a polysilicon layer 206, an anode 208, a cathode 210, and an oxide film 212.

The substrate 200 is a substrate formed of Si. The substrate 200 is formed, for example, from a monocrystalline Si wafer. On the substrate 200, the buried oxide film layer 202 is formed as an insulating film. The buried oxide film layer 202 is formed, for example, from a thin film of SiO₂, and isolates various elements formed on the buried oxide film layer 202 from the substrate 200. The SOI 2 is constituted including the Si substrate, the oxide film formed on the Si substrate, and the various elements formed on the oxide film as explained above.

On the buried oxide film layer 202, the active layer 204 is formed. The active layer 204 is formed by implanting ions into the Si layer formed on the buried oxide film layer 202. The oxide film 212 is formed on the active layer 204 formed in the above manner, and the polysilicon layer 206, the anode 208, and the cathode 210 are formed in the oxide film 212. Note that the formation process is not limited to the above order but may be executed in an appropriate order.

The polysilicon layer 206 is formed of polysilicon. The anode 208 and the cathode 210 are formed, for example, polysilicon or metal. These are arranged in a state where they are insulated from each other by the oxide film 212. The anode 208 is connected to a region 204p+ having a polarity of p+ of the active layer 204, and the cathode 210 is connected to a region 204n+ having a polarity of n+ of the active layer 204. The region 204p+ and the region 204n+ are connected by a region 204n− of the active layer 204 having a polarity of n−. These regions may be formed by implanting predetermined ions with predetermined energy.

When the ion implantation is performed in the active layer 204, the formation of the polysilicon layer 206 as in the process of the gate formation of the MOSFET makes it possible to use the polysilicon layer 206 as a mask at the time of performing ion implantation, for example, in the region 204p+ and the region 204n+. In other words, the polysilicon layer 206 is not an essential configuration as a device but may be removed after the process.

The PN junction diodes provided in the ESD protection circuitry 12 in each of the above embodiments may be formed on the SOI substrate as in the above manner. The PN junction diode formed as in the above manner is not directly connected to the substrate 200 and thus can operate as an ideal two-terminal element of only an anode and a cathode. In the case where the LNA 1 is formed on the SOI 2, the relationship in area of the PN junction diodes according to each of the above embodiments is established, thereby achieving ESD protection with respect to the LNA 1, suppressing the waste of the area for arrangement, and realizing the easiness of the formation in the process.

In the embodiments explained herein, having the same circuitry constant does not need to be strictly the same but only needs to be the same, for example, within a range where even the elements having the same circuitry constant have individual differences. Further, this also applies to claims, and being the same does not mean being strictly the same, but may have a small error such as individual difference.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, in all of the above-explained embodiments, the n-type MOSFET may be a p-type MOSFET according to the situation and the p-type MOSFET may be an n-type MOSFET according to the situation. Further, as the MOSFET, another transistor having the same function, for example, the one functioning as a switching element by voltage, current, or another external switching signal, such as a bipolar transistor may be used. For example, in the case of using the bipolar transistor, the gate, source, drain in the explanation in this specification and claims may be replaced in reading with an appropriate combination of a base, a collector (emitter), and an emitter (collector), respectively. In any replacement in reading, the physical amount used for switching such as the magnitude of the voltage to be applied to the gate, the current to be applied to the base or the like can be appropriately replaced in reading so as to appropriately perform the operation equivalent to that of the one having the above-described functions by the characteristics of the elements.

1. A high-frequency amplifier circuitry comprising:
a capacitor having one end connected to an input node;
a first transistor having a gate connected to another end of the capacitor, and having a source grounded via an inductor;
a second transistor cascode-connected with the first transistor, having a gate grounded in a high-frequency manner, and outputting from a drain thereof a signal made by amplifying a signal output from a drain of the first transistor; and
an ESD protection circuitry comprising a plurality of PN junction diodes, having a first terminal connected to the input node, having a second terminal grounded, and having a third terminal connected to the source of the first transistor.

2. The high-frequency amplifier circuitry according to claim 1, wherein
in the plurality of PN junction diodes provided in the ESD protection circuitry, a sum of junction areas of the PN junction diodes included in a path for passing a forward current from the second terminal to the first terminal and a path for passing a forward current from the third terminal to the first terminal is equal to a junction area of the PN junction diode for passing a forward current from the first terminal to the third terminal.

3. The high-frequency amplifier circuitry according to claim 2, wherein the PN junction diodes provided in the ESD protection circuitry comprise:
a first diode having a cathode connected to the first terminal;
a second diode having a cathode connected to an anode of the first diode, and having an anode connected to the second terminal;
a third diode having a cathode connected to the first terminal, and having an anode connected to the anode of the first diode;
a fourth diode having a cathode connected to the anode of the third diode, and having an anode connected to the third terminal;
a fifth diode having an anode connected to the first terminal; and
a sixth diode having an anode connected to a cathode of the fifth diode, and having a cathode connected to the third terminal.

4. The high-frequency amplifier circuitry according to claim 3, wherein:
a junction area of the first diode is equal to a junction area of the second diode;
a junction area of the third diode is equal to a junction area of the fourth diode;
a junction area of the fifth diode is equal to a junction area of the sixth diode; and
a sum of the junction area of the first diode and the junction area of the third diode is equal to the junction area of the fifth diode.

5. The high-frequency amplifier circuitry according to claim 3, further comprising
a clamp circuitry connected between the drain of the first transistor and a ground potential.

6. The high-frequency amplifier circuitry according to claim 1, wherein
a junction area of the PN junction diode provided in the ESD protection circuitry is defined so that when a voltage between the gate and the source of the first transistor is a voltage reaching a breakdown withstand voltage causing a gate breakdown, the voltage between the gate and the drain is equal to a voltage of the breakdown withstand voltage.

7. The high-frequency amplifier circuitry according to claim 1 formed on an SOI (Silicon On Insulator) substrate.

8. The high-frequency amplifier circuitry according to claim 1, further comprising:
an SPnT (Single-Pole/n-Throw) switch configured to select signals of a plurality of frequencies and output an input signal; and
an input matching circuitry configured to match the input signal between modes.

9. The high-frequency amplifier circuitry according to claim 4, further comprising
a clamp circuitry connected between the drain of the first transistor and a ground potential.
